(19) United States
(12) Patent Application Publication
(10) Pub. No.: US 2016/0091190 A1
(43) Pub. Date: Mar. 31, 2016

(54) STRUCTURE OF LED HEAT DISSIPATING SUBSTRATE AND METHOD OF MANUFACTURING SUCH SUBSTRATE

(71) Applicant: Wei-Chia Huang, Hsinchu City (TW)

(72) Inventor: Wei-Chia Huang, Hsinchu City (TW)

(21) Appl. No.: 14/501,048

(22) Filed: Sep. 30, 2014

(51) Int. Cl. F21V 29/70; F21V 23/00; H05K 1/02

(52) U.S. Cl. CPC F21V 29/70; H05K 1/028; H05K 1/0203; F21V 23/005; H05K 2201/066; H05K 2201/10106; F21Y 2101/02

(57) ABSTRACT

A structure of a LED heat dissipating substrate and a method of manufacturing such substrate are provided. Material removing process are mainly performed to make a first conducting board, a second conducting board and each of third conducting boards be disconnected from each other. In addition, positive and negative wires are connected to the first and second conducting boards to power and excite a LED die. Thus, the structure can be curved, have the unlimited length, can be continously produced without the conventional electroplating, etching and water cleaning processes, so that no wastewater is produced and the environment protection object is achieved.

### BACKGROUND OF THE INVENTION

(1) Field of the Invention

The invention relates to a light-emitting diode (LED) substrate, and more particularly to a structure of a flexible LED heat dissipating substrate and a method of manufacturing such the substrate without conventional electroplating and etching processes.

(2) Description of the Prior Art

LED products are widely used because they have the advantages, such as energy saving, power-saving, high efficiency, short reaction time and long lifetime cycle, and contain no mercury to have the environment protection object. The applications include the LCD backlights, mobile phone backlights, signal lights, vehicles, art illumination, building illumination, stage lighting control, family illumination and the like. However, only about 15 to 20% of the input power of the LED is converted into light, and about 80 to 85% of the electrical energy is converted into the heat energy. If the heat generated by the lighting LED cannot be dissipated, the interface temperature of the LED is too high to affect the light emitting efficiency, stability and lifetime. The lifetime of the LED gets shorter as the temperature gets higher.

When the interface temperature rises from 25° C. to 100° C. , the light emitting efficiency degrades 20% to 75%, wherein the yellow light has the most serious degradation of 75%. In addition, when the operation environment temperature of the LED gets higher, the lifetime of the LED is also shortened. In order to decrease the interface temperature of the LED, the LED package process has to be improved to decrease the thermal resistance of the LED module. The most important issue contains the material selection of the heat dissipating substrate and the improvement of the thermal conductivity of the dielectric layer (insulating layer).

In the LED package process, one single LED chip or multiple LED chips are adhered to the heat dissipating metal plate through the solder or adhesive, and a transparent epoxy resin package material is coated on or above the chip, and then a lens is disposed to cover the package material to construct a LED lamp applied to the illumination, indicator or backlight source. According to different applications, multiple LEDs are assembled on the same circuit board. Thus, the circuit board not only supports the LEDs but also plays the role of heat dissipating. Generally, the treatment flow of the heat dissipating aluminum substrate includes (oil removing/acid cleaning→water cleaning microetching/mechanical plate grinding→water cleaning→drying)→lift-off PE film→film adhering (pre-heating→film adhering→cooling)→exposure→lift-off PET film→film removing→development (development→water cleaning→drying)→etching. Because the heat dissipating aluminum substrate cannot be bent, the special curved surface or special requirement cannot be satisfied. Furthermore, the etching and electroplating processes tend to cause the environment water pollution and the CO₂ emission (10 Kg of CO₂ is produced to manufacture 1 Kg of aluminum), and cannot achieve the effective objects of energy saving and carbon reduction in the environment.

The detailed characteristics and advantages of the invention will be described in the embodiment, the contents of which are sufficient for those skilled in the art to understand the technological contents and implement the invention. In addition, according to the contents, claims and drawings disclosed in the specification, those skilled in the art may easily understand the objects and advantages of the invention.

### SUMMARY OF THE INVENTION

A main object of the invention is to provide a LED heat dissipating substrate, which can be curved and curled, has the unlimited length and can be manufactured continuously without the conventional electroplating and etching processes. Thus, no water cleaning is needed, and no wastewater is produced. The graphene heat dissipating layer is used instead of the conventional aluminum serving as the heat dissipating material. The high-energy-consuming aluminum is not used, and no wastewater is produced to decrease the generated CO₂. So, the energy saving and carbon reduction objects can be achieved.

To achieve the above-identified objects, the invention provides a method of manufacturing a LED heat dissipating substrate, comprising the steps of: (a) performing a first material removing process on a flexible substrate to form a plurality of first material removed regions and define a first conducting board, a second conducting board and a plurality of third conducting boards connected to one another; (b) covering a plurality of cover films on a surface of the flexible substrate with each of the cover films partially shielding the neighboring first material removed regions; (c) forming a plurality of second material removed regions on the cover films while performing a second material removing process on the flexible substrate, to make the first conducting board, the second conducting board and each of the third conducting boards be disconnected from one another; (d) disposing a heat sink on a back side of the flexible substrate; (e) connecting a plurality of LED dies between the third conducting boards, respectively; (f) connecting the first conducting board and the third conducting board at a frontmost end of the flexible substrate to a first conducting section, and connecting the second conducting board and the third conducting board disposed at a rearmost end of the flexible substrate to a second conducting section; and (g) connecting a positive wire and a negative wire to the first conducting board and the second conducting board, respectively.

According to one embodiment of the invention, the first material removed region in step (a) defines a first material removed space, a second material removed space and a third material removed space connected between the first material removed space and the second material removed space.

According to one embodiment of the invention, the heat sink is made of graphene.

The structure of the LED heat dissipating substrate manufactured by the above-mentioned steps includes: a flexible substrate formed with a plurality of first material removed regions, wherein the flexible substrate is defined, by the first material removed regions, with a first conducting board, a second conducting board and third conducting boards, wherein two ends of the third conducting board define a first conducting portion and a second conducting portion; a plurality of cover films each disposed on a surface of the flexible substrate and partially shielding the neighboring first material removed regions, wherein each of the cover films is formed with a plurality of second material removed regions with the first conducting board, the second conducting board and each of the third conducting boards being disconnected from one another; a heat sink disposed on the flexible substrate and away from a side surface of the cover film; a plurality of LED dies each connected to the first conducting portion and the second conducting portion of the different third conducting boards; a first conducting section to be connected to the first conducting board and the third conducting board at a frontmost end of the flexible substrate; and a second conducting section to be connected to the second conducting board and the third conducting board disposed at a rearmost end of the flexible substrate.

According to one embodiment of the invention, the first material removed region defines a first material removed space, a second material removed space and a third material removed space connected between the first material removed space and the second material removed space

According to one embodiment of the invention, the first conducting portion and the second conducting portion are disposed on two sides of the third material removed space, respectively, and the first conducting board and the second conducting board are disposed outside the first material removed space and the second material removed space.

According to one embodiment of the invention, the cover film shields neighboring portions of the first material removed space and the second material removed space of the first material removed region.

According to one embodiment of the invention, wherein the second material removed regions on the cover films correspond to a position between the neighboring first material removed spaces and a position between the neighboring second material removed spaces.

According to one embodiment of the invention, the structure further includes a positive wire and a negative wire connected to the first conducting board and the second conducting board, respectively.

Further aspects, objects, and desirable features of the invention will be better understood from the detailed description and drawings that follow in which various embodiments of the disclosed invention are illustrated by way of examples.

### BRIEF DESCRIPTION OF THE DRAWINGS

FIG. 1 is a block diagram showing steps of a preferred embodiment of the invention.

FIG. 2a shows pictorial views of structures in the steps of the preferred embodiment of the invention.

FIG. 2b shows other pictorial views of structures in the steps of the preferred embodiment of the invention.

FIG. 3 is a pictorial view showing the preferred embodiment of the invention.

FIG. 4 shows the pictorial view of the material removed position in the second material removing process of the invention.

### DETAILED DESCRIPTION OF THE PREFERRED EMBODIMENTS

The embodiment of the invention will be described in the following. Other advantages and effects of the invention will be better understood, by those skilled in the art, from the detailed description of the invention.

Structures, scales, sizes and the like depicted in the accompanying drawings are provided in conjunction with the specification for the purpose of illustration only to facilitate those skilled in the art in understanding and reading, and are not for the purpose of restricting the implementable condition of the invention and have no substantial technological meanings. Any structural modification, ratio change or size adjustment still falls within the range covered by the disclosed technology of the invention without affecting the effects and objects of the invention. Meanwhile, the terms, such as “a”, “an”, “one”, “two”, “on” and “above” disclosed in the specification, are provided for the facilitating of the understanding of the specification, and do not intend to restrict the implementable range of the invention. The changes or adjustments of the relative relationship are still deemed as falling within the implementable range of the invention without substantially modifying the technological contents.

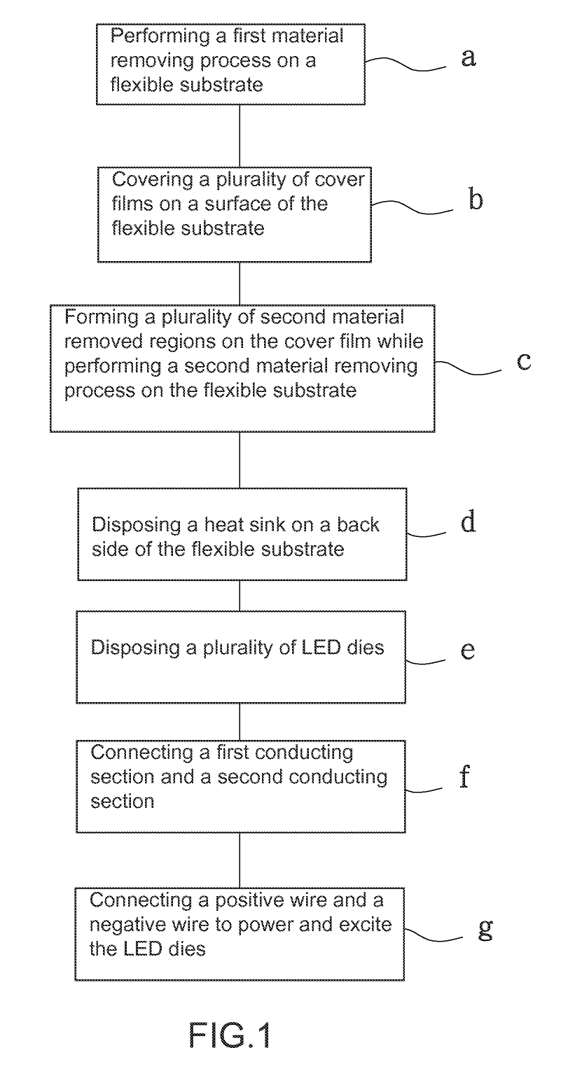

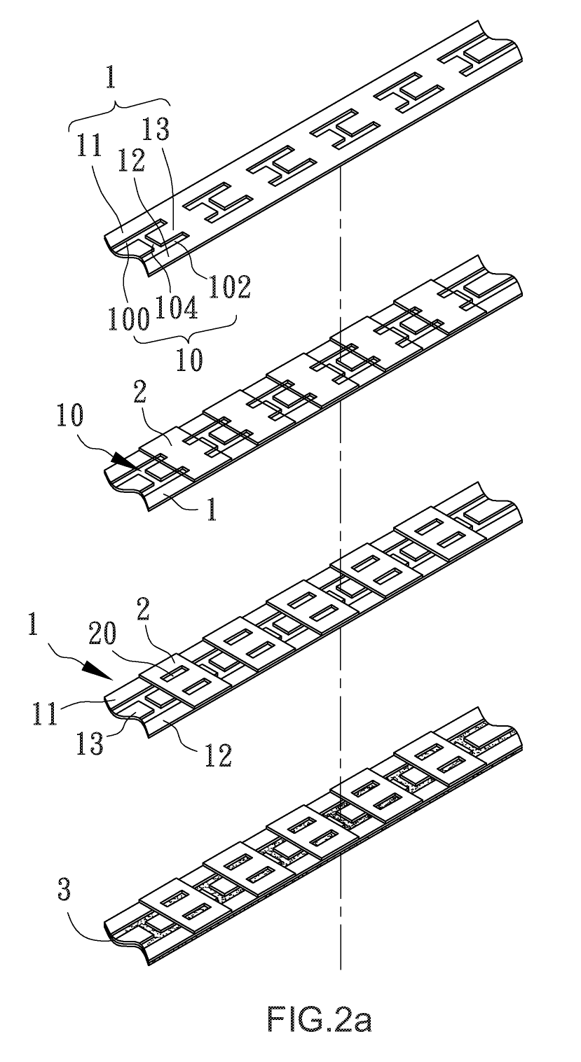

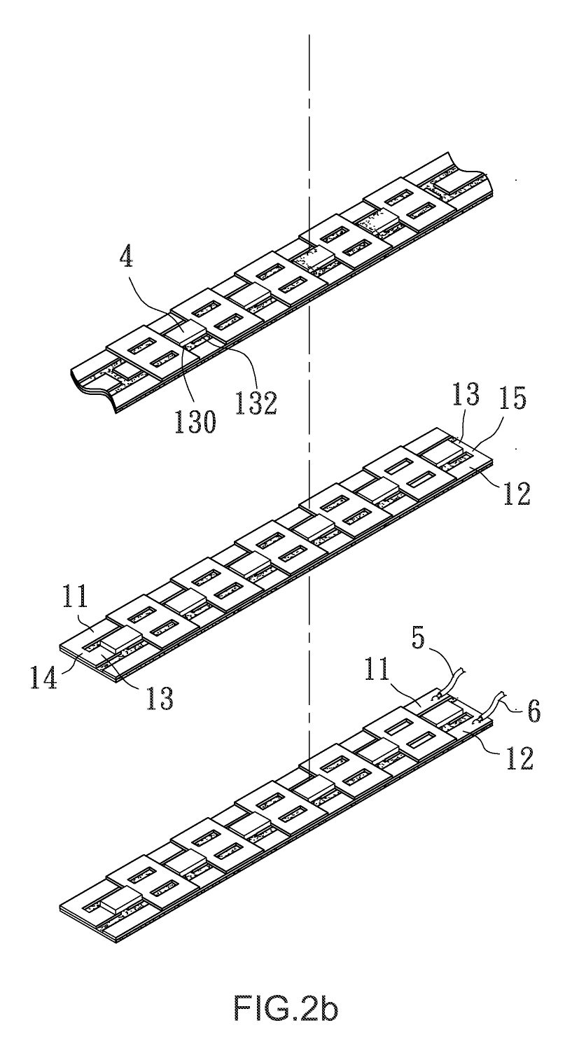

FIG. 1 is a block diagram showing steps of a preferred embodiment of the invention. FIGS. 2a and 2b show pictorial views of structures in steps of the preferred embodiment of the invention. Referring to FIGS. 1, 2a and 2b, the method of manufacturing a LED heat dissipating substrate of the invention includes the following steps of: (a) performing a first material removing process on a flexible substrate; (b) covering a plurality of cover films on a surface of the flexible substrate; (c) forming a plurality of second material removed regions on the cover films while performing a second material removing process on the flexible substrate; (d) disposing a heat sink on a back side of the flexible substrate; (e) disposing a plurality of LED dies; (f) connecting a first conducting section and a second conducting section; and (g) connecting a positive wire and a negative wire to power and excite the LED dies.

In the step (a), a first material removing process is mainly performed on the flexible substrate 1 by way of a non-etching method, such as pressing, laser cutting or the like, so that the flexible substrate 1 is formed with a plurality of first material removed regions 10. The first material removed region 10 defines a first material removed space 100, a second material removed space 102 and a third material removed space 104 connected between the first material removed space 100 and the second material removed space 102. Meanwhile, a first conducting board 11, a second conducting board 12 and a plurality of third conducting boards 13 connected to one another are defined. In the step (b), a plurality of cover films 2 covers the surface of the flexible substrate 1. Each cover film 2 needs to partially shield the neighboring first material removed regions 10. In the step (c), the cover film 2 is formed with second material removed regions 20 while the second material removing process is performed on the flexible substrate 1 to make the first conducting board 11, the second conducting board 12 and each of the third conducting boards 13 be disconnected from one another. In the step (d), a heat sink 3 (made of graphene) is mainly disposed on the back side of the flexible substrate 1. In the step (e), each LED die 4 is connected between the third conducting boards 13. Then, in the step (f), the first conducting board 11 and the third conducting board 13 on the frontmost end of the flexible substrate 1 are connected to a first conducting section 14, and a second conducting section 15 is connected between the second conducting board 12 and the third conducting board 13 disposed at a rearmost end of the flexible substrate. Finally, in the step (g), a positive wire 5 and a negative wire 6 are connected to the first conducting board 11 and the second conducting board 12, respectively, to power and excite the LED die. Thus, the LED heat dissipating substrate of the invention can be curved, has the unlimited length, and can be continuously manufactured without the conventional electroplating, etching and water cleaning processes. So, no wastewater is produced and the environment protection object can be achieved.

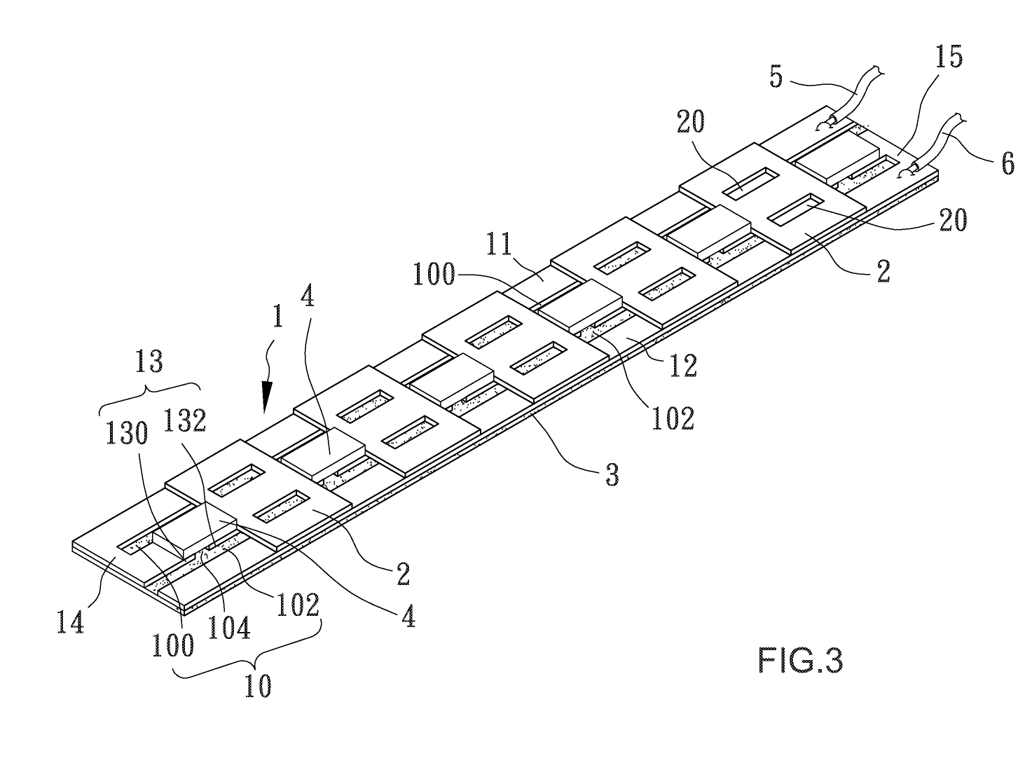

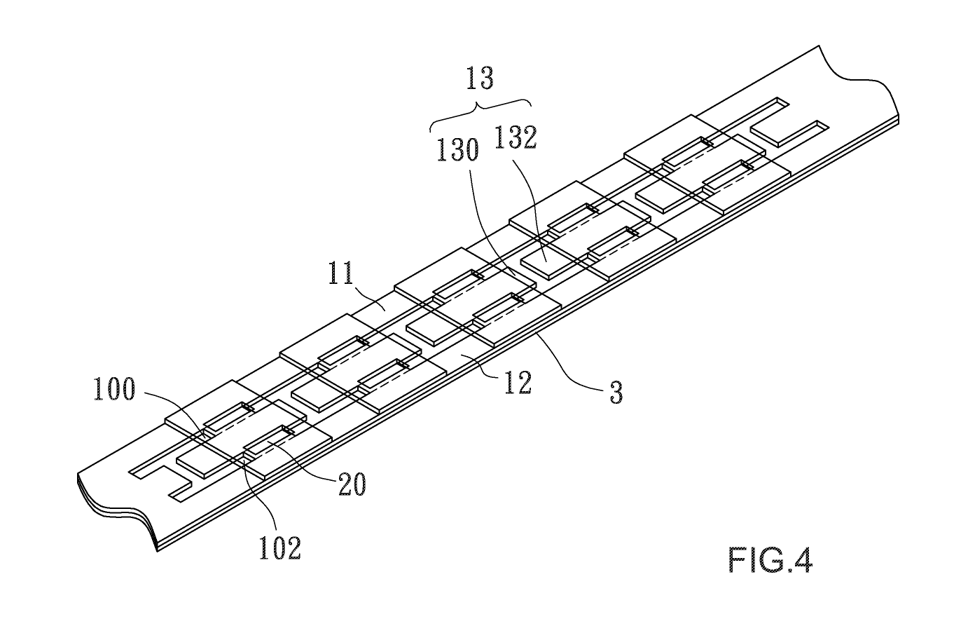

FIG. 3 is a pictorial view showing the preferred embodiment of the invention. FIG. 4 shows the pictorial view of the material removed position in the second material removing process of the invention. Referring to FIGS. 3 and 4, the structure of the LED heat dissipating substrate manufactured by the above-mentioned steps mainly includes the flexible substrate 1, the cover film 2, the heat sink 3, the LED die 4, the first conducting section 14 and the second conducting section 15. The flexible substrate 1 is formed with a plurality of first material removed regions 10, which defines a first material removed space 100, a second material removed space 102 and a third material removed space 104 connected between the first material removed space 100 and the second material removed space 102. A first conducting portion 130 and a second conducting portion 132 are defined on two sides of the third material removed space 104, respectively. In addition, the first conducting board 11 and the second conducting board 12 are disposed outside the first material removed space 100 and the second material removed space 102. The first conducting portion 130 and the second conducting portion 132 are defined on two ends of the third conducting board 13. In is to be noted that the two sides of the third material removed space 104 are defined by two third conducting boards 13.

In addition, the cover film 2 is disposed on the surface of the flexible substrate 1 and partially shields the neighboring first material removed regions 10, and each cover film 2 is formed with a plurality of second material removed regions 20, wherein the cover film 2 shields neighboring portions of the first material removed space 100 and the second material removed space 102 of the first material removed region 10. The second material removed regions 20 on the cover films 2 correspond to a position between the neighboring first material removed spaces 100, and a position between the neighboring second material removed spaces 102. Thus, when the second material removed region 20 is formed by way of pressing, the second material removing process is performed on the materials between the neighboring first material removed spaces 100 and between the neighboring second material removed spaces 102, so that the first conducting board 11, the second conducting board 12 and each third conducting board 13 are disconnected from one another. Thereafter, the heat sink 3 (made of graphene) is disposed on the flexible substrate 1 and away from a side surface of the cover film 2.

Furthermore, each LED die 4 is connected to the first conducting portion 130 and the second conducting portion 132 of the different third conducting boards 13 to form a serial or cascaded connection. The first conducting section 14 is connected between the first conducting board 11 and the third conducting board 13 on the frontmost end of the flexible substrate 1. The second conducting section 15 is connected between the second conducting board 12 and the third conducting board 13 on the rearmost end of the flexible substrate 1. Thereafter, the positive wire 5 and the negative wire 6 are connected to the first conducting board 11 and the second conducting board 12, respectively, to power and excite each LED die 4. Thus, the structure can be curved, has the unlimited length, can be continuously produced without the conventional electroplating, etching and water cleaning processes, so that no wastewater is produced and the energy saving and carbon reduction objects are achieved.

New characteristics and advantages of the invention covered by this document have been set forth in the foregoing description. It is to be expressly understood, however, that the drawings are for the purpose of illustration only and are not intended as a definition of the limits of the invention. Changes in methods, shapes, structures or devices may be made in details without exceeding the scope of the invention by those who are skilled in the art. The scope of the invention is, of course, defined in the language in which the appended claims are expressed.

What is claimed is:

1. A method of manufacturing a LED heat dissipating substrate, comprising the steps of:
(a) performing a first material removing process on a flexible substrate to form a plurality of first material removed regions and define a first conducting board, a second conducting board and a plurality of third conducting boards connected to one another;
(b) covering a plurality of cover films on a surface of the flexible substrate with each of the cover films partially shielding the neighboring first material removed regions;
(c) forming a plurality of second material removed regions on the cover films while performing a second material removing process on the flexible substrate, to make the first conducting board, the second conducting board and each of the third conducting boards be disconnected from one another;
(d) disposing a heat sink on a back side of the flexible substrate;
(e) connecting a plurality of LED dies between the third conducting boards, respectively;
(f) connecting the first conducting board and the third conducting board at a frontmost end of the flexible substrate to a first conducting section, and connecting the second conducting board and the third conducting board disposed at a rearmost end of the flexible substrate to a second conducting section; and
(g) connecting a positive wire and a negative wire to the first conducting board and the second conducting board, respectively.

2. The method according to claim 1, wherein the first material removed region in step (a) defines a first material removed space, a second material removed space and a third material removed space connected between the first material removed space and the second material removed space.

3. The method according to claim 1, wherein the heat sink is made of graphene.

4. A structure of a LED heat dissipating substrate, the structure comprising:
a flexible substrate formed with a plurality of first material removed regions, wherein the flexible substrate is defined, by the first material removed regions, with a first conducting board, a second conducting board and third conducting boards, wherein two ends of the third conducting board define a first conducting portion and a second conducting portion;
a plurality of cover films each disposed on a surface of the flexible substrate and partially shielding the neighboring first material removed regions, wherein each of the cover films is formed with a plurality of second material removed regions with the first conducting board, the second conducting board and each of the third conducting boards being disconnected from one another;
a heat sink disposed on the flexible substrate and away from a side surface of the cover film;
a plurality of LED dies each connected to the first conducting portion and the second conducting portion of the different third conducting boards;
a first conducting section to be connected to the first conducting board and the third conducting board at a frontmost end of the flexible substrate; and
a second conducting section to be connected to the second conducting board and the third conducting board disposed at a rearmost end of the flexible substrate.

5. The structure according to claim 4, wherein the first material removed region defines a first material removed space, a second material removed space and a third material removed space connected between the first material removed space and the second material removed space.

6. The structure according to claim 5, wherein the first conducting portion and the second conducting portion are disposed on two sides of the third material removed space, respectively, and the first conducting board and the second conducting board are disposed outside the first material removed space and the second material removed space.

7. The structure according to claim 6, wherein the cover film shields neighboring portions of the first material removed space and the second material removed space of the first material removed region.

8. The structure according to claim 7, wherein the second material removed regions on the cover films correspond to a position between the neighboring first material removed spaces and a position between the neighboring second material removed spaces.

9. The structure according to claim 4, further comprising a positive wire and a negative wire connected to the first conducting board and the second conducting board, respectively.
